(19) United States
(12) Patent Application Publication
(10) Pub. No.: US 2024/0097080 A1
(43) Pub. Date: Mar. 21, 2024

(54) LIGHT EMITTING MODULE

(71) Applicant: PROLIGHT OPTO TECHNOLOGY CORPORATION, Taoyung City (TW)

(72) Inventors: Chen-Lun HSING CHEN, Taoyuan City (TW); Jung-Hao HUNG, Taoyuan City (TW); Ya-Yu HUNG, Taoyuan City (TW); Yi-Ting KUO, Taoyuan City (TW)

(21) Appl. No.: 18/219,069

(22) Filed: Jul. 6, 2023

(30) Foreign Application Priority Data
Sep. 16, 2022 (TW) 111210096

(51) Int. Cl. H01L 33/50; H01L 33/60

(52) U.S. Cl. CPC H01L 33/502; H01L 33/508; H01L 33/60

(57) ABSTRACT

A light emitting module includes a carrier, a light emitting element, a reflection layer, and a fluorescent layer. The light emitting element is disposed on the carrier. The reflection layer is disposed on the carrier and surrounds the light emitting element. The fluorescent layer covers at least part of the light emitting element. The disadvantages of over broad light emitting angle and low illuminance may be solved. Comparing with the related art, the present disclosure achieves an object of increasing the illuminance by at least 10%.

### BACKGROUND OF THE DISCLOSURE

### Technical Field

The present disclosure relates to a light emitting module, particularly relates to a light emitting module with a light emitting element surrounded by a reflection layer.

### Description of Related Art

The light emitting diode (LED) is a semiconductor element, and transforms the electrical energy to the optical energy through the semiconductor compound to achieve the light emitting effect. The LED has the advantages of long service life, high stability, and low power consumption, thereby being widely used in the illumination. Regarding the illumination product using LED in the related art, the general adopted architecture is covering the LED with the colloid material having phosphor, and the phosphor is excited by the LED to radiate specific frequency spectrum.

However, except the bottom surface of the LED fixed on the substrate, the other surfaces of the LED are covered by the fluorescent layer. Thus, the fluorescent layer may react to the light from the LED in all direction, and the lighting angle may be over broad along the light emitting direction (such as the direction vertical to the substrate) and the illuminance may not be increased.

In view of this, the inventors have devoted themselves to the aforementioned related art, researched intensively try to solve the aforementioned problems.

### SUMMARY OF THE DISCLOSURE

The purpose of the disclosure is to provide a light emitting module, which may overcome the disadvantages of over broad light emitting angle and low illuminance, and comparing with the related art, the present disclosure may increase the illuminance by at least 10%.

In order to achieve the purpose, the light emitting module of the disclosure includes a carrier, a light emitting element, a reflection layer, and a fluorescent layer. The light emitting element is disposed on the carrier. The reflection layer is disposed on the carrier, and surrounds the light emitting element. The fluorescent layer covers at least part of the light emitting element.

In some embodiments, the light emitting element includes a light emitting diode.

In some embodiments, the fluorescent layer is structured as a curved surface or a flat surface on the light emitting element.

In some embodiments, the fluorescent layer further covers a least part of the reflection layer.

In some embodiments, a side wall of the reflection layer is structured as a first step surface.

In some embodiments, a second step surface is disposed between the carrier and the reflection layer.

In some embodiments, a third step surface is disposed between the reflection layer and the fluorescent layer.

In some embodiments, the fluorescent layer includes an irregular structure in a non-uniform distribution manner.

In some embodiments, the irregular structure includes at least two fluorescent particles with different sizes.

In some embodiments, the irregular structure is only disposed on a light emitting surface of the fluorescent layer.

In summary, the light emitting module of the disclosure uses the reflection layer capable of surrounding the side wall of the light emitting element. As a result, part of the light outputted from the light emitting element may not escape from the side wall of the light emitting element and may not cause energy waste. Further, the reflection layer restricts the light emitting angle of the light emitting element, and makes more light enter the fluorescent layer to increase the illuminance of the light emitting module of the disclosure. Comparing to the illumination product in the related art, the light emitting module of the disclosure may have higher illuminance.

It is worth mentioning that the reflection layer may include a colloid composed of high-molecular material or metal oxide (such as, TiO₂, etc.) in white color with high reflectivity, here is not intended to be limiting.

Therefore, the light emitting module of the disclosure may overcome the disadvantages of over broad light emitting angle and low illuminance, and comparing with the related art, the present disclosure may increase the illuminance by at least 10%.

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings.

### BRIEF DESCRIPTION OF THE DRAWINGS

FIG. 1 is a structural perspective view of the first embodiment of the light emitting module in the disclosure.

FIG. 2 is a structural perspective view of the second embodiment of the light emitting module in the disclosure.

FIG. 3 is a structural perspective view of the third embodiment of the light emitting module in the disclosure.

FIG. 4 is a structural perspective view of the fourth embodiment of the light emitting module in the disclosure.

FIG. 5 is a structural perspective view of the fifth embodiment of the light emitting module in the disclosure.

FIG. 6 is a structural perspective view of the sixth embodiment of the light emitting module in the disclosure.

FIG. 7 is a structural perspective view of the seventh embodiment of the light emitting module in the disclosure.

FIG. 8 is a structural perspective view of the eighth embodiment of the light emitting module in the disclosure.

FIG. 9 is a structural perspective view of the ninth embodiment of the light emitting module in the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

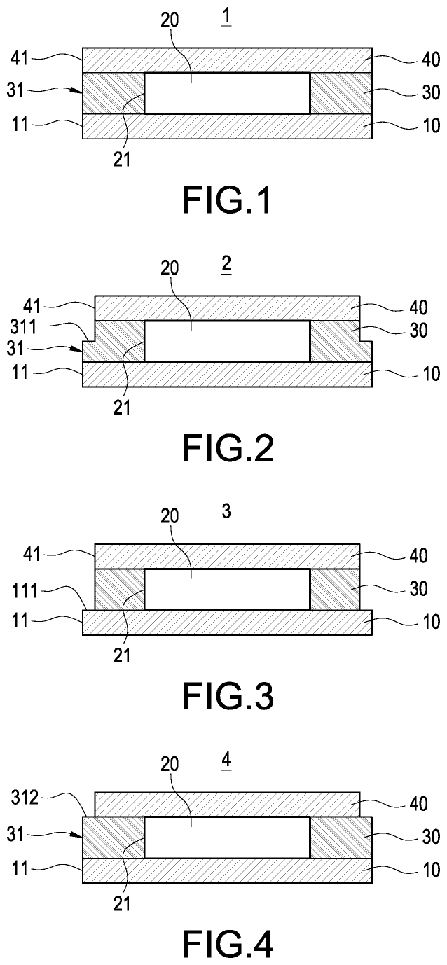

FIG. 1 is a structural perspective view of the first embodiment of the light emitting module 1 in the disclosure.

Referring to FIG. 1, the light emitting module 1 of the disclosure includes a carrier 10, a light emitting element 20, a reflection layer 30, and a fluorescent layer 40.

The carrier 10 may include die holder or printed circuit board (PCB) made by FR-4 substrate. FR-4 substrate includes at least one of fiberglass, epoxy resin, and BT resin. The BT resin is a thermosetting resin made by bismaleimide (BMI) and triazine as main resin composition and adding epoxy resin, polyphenylene ether (PPE), or allyl compound as modified component, here is not intended to be limiting.

The light emitting element 20 is disposed on the carrier 10.

In some embodiments, the light emitting element 20 may include a light emitting diode (LED). The LED may include red-light LED (such as, AlGaAs, GaAs P, AlGaInP, GaP:ZnO), orange-light LED (such as, GaAsP, AlGaInP, GaP:X), yellow-light LED (such as, GaAsP, AlGaInP, GaP:N), green-light LED (such as, InGaN, GaN, GaP, AlGaInP, AlGaP), blue-light LED (such as, ZnSe, InGaN, SiC), and/or purple-light LED (such as, InGaN) in the visible light category, and/or may include infrared LED (such as, GaAs, AlGaAs) and/or ultraviolet LED (such as, diamond, AlN, AlGaN, AlGaInN), etc. Further, the LED may also include organic light-emitting diode (OLED), here is not intended to be limiting.

The reflection layer 30 is disposed on the carrier 10 and surrounds the light emitting element 20.

In some embodiments, the reflection layer 30 may include a colloid composed of high-molecular material or metal oxide (such as, TiO₂, etc.) in white color with high reflectivity, here is not intended to be limiting.

In some embodiments, the reflection layer 30 surrounds and is directly attached to whole side wall 21 of the light emitting element 20, and does not cover the top surface of the light emitting element 20, here is not intended to be limiting. Further, based on the principle of surface tension, the top surface of the reflection layer 30, which surrounds whole side wall 21 of the light emitting element 20, may be structured with some micro concaves of U-shaped groove. The U-shaped groove surrounds the periphery of the light emitting element 20, here is not intended to be limiting.

In some embodiments, the side wall 31 of the reflection layer 30 is aligned with the side wall 11 of the carrier 10, here is not intended to be limiting.

It is worth mentioning that the disclosure may increase the illuminance by at least 10% compared to the related art through introducing the reflection layer 30, here is not intended to be limiting.

The fluorescent layer 40 covers at least part of the light emitting element 20.

In some embodiments, the fluorescent layer 40 may include one to three types of phosphors and optical colloid material uniformly mixed with each other. The fluorescent layer 40 may be further mixed with fluoride phosphor to improve color rendering index (CRI) or decrease blue light intensity, here is not intended to be limiting.

In some embodiments, the fluorescent layer 40 is formed as a flat surface on the whole light emitting element 20, and the fluorescent layer 40 further cover the whole reflection layer 30, here is not intended to be limiting.

In some embodiments, the side wall 41 of the fluorescent layer 40 is aligned with the side wall 31 of the reflection layer 30, here is not intended to be limiting.

Therefore, the light emitting module 1 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 1 of the disclosure. Comparing to the illumination product in the related art, the light emitting module 1 of the disclosure may have higher illuminance.

In some embodiments, the light emitting module 1 of the disclosure may increase the illuminance by at least 10% compared to the related art.

FIG. 2 is a structural perspective view of the second embodiment of the light emitting module 2 in the disclosure.

The light emitting module 2 in the second embodiment of the disclosure is similar to the light emitting module 1 in the first embodiment, the difference is that the side wall 31 of the reflection layer 30 is structured with a first step surface 311, here is not intended to be limiting.

Therefore, the light emitting module 2 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 2 of the disclosure. Comparing to the illumination product in the related art, the light emitting module 2 of the disclosure may have higher illuminance.

FIG. 3 is a structural perspective view of the third embodiment of the light emitting module 3 in the disclosure.

The light emitting module 3 in the third embodiment of the disclosure is similar to the light emitting module 1 in the first embodiment, the difference is that a second step surface 111 is disposed between the carrier 10 and the reflection layer 30, here is not intended to be limiting.

In some embodiments, part of the top surface of the carrier 10, which is not covered by the reflection layer 30, forms the second step surface 111, here is not intended to be limiting.

Therefore, the light emitting module 3 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 3 of the disclosure. Comparing to the illumination product in the related art, the light emitting module 3 of the disclosure may have higher illuminance.

FIG. 4 is a structural perspective view of the fourth embodiment of the light emitting module 4 in the disclosure.

The light emitting module 4 in the fourth embodiment of the disclosure is similar to the light emitting module 1 in the first embodiment, the difference is that a third step surface 312 is disposed between the reflection layer 30 and the fluorescent layer 40.

In some embodiments, part of the top surface of the reflection layer 30, which is not covered by the fluorescent layer 40, forms the third step surface 312, here is not intended to be limiting.

Therefore, the light emitting module 4 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 4 of the disclosure. Comparing to the illumination product in the related art, the light emitting module 4 of the disclosure may have higher illuminance.

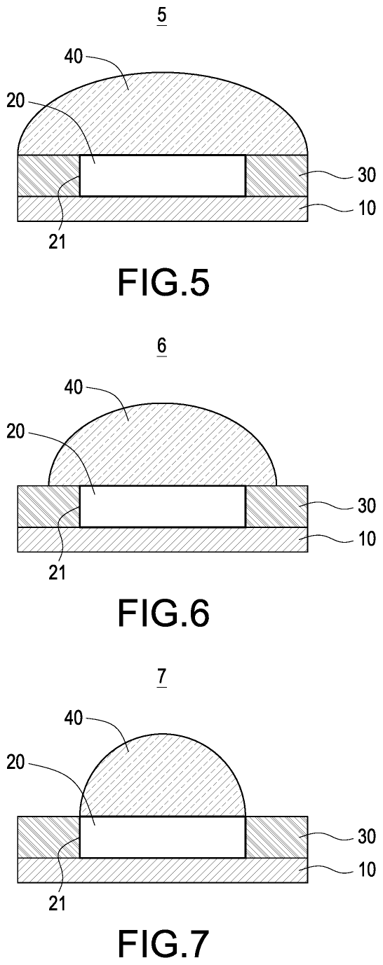

FIG. 5 is a structural perspective view of the fifth embodiment of the light emitting module 5 in the disclosure.

The light emitting module 5 in the fifth embodiment of the disclosure is similar to the light emitting module 1 in the first embodiment, the difference is that the fluorescent layer 40 is structured as a curved surface on the light emitting element 20, here is not intended to be limiting.

Therefore, the light emitting module 5 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 5 of the disclosure. Comparing to the illumination product in the related art, the light emitting module 5 of the disclosure may have higher illuminance.

FIG. 6 is a structural perspective view of the sixth embodiment of the light emitting module 6 in the disclosure.

The light emitting module 6 in the sixth embodiment of the disclosure is similar to the light emitting module 4 in the fourth embodiment, the difference is that the fluorescent layer 40 is structured as a curved surface on the light emitting element 20, here is not intended to be limiting.

Therefore, the light emitting module 6 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 6 of the disclosure. Comparing to the illumination product in the related art, the light emitting module 6 of the disclosure may have higher illuminance.

FIG. 7 is a structural perspective view of the seventh embodiment of the light emitting module 7 in the disclosure.

The light emitting module 7 in the seventh embodiment of the disclosure is similar to the light emitting module 6 in the sixth embodiment, the difference is that the fluorescent layer 40 only covers the whole light emitting element 20 and does not cover the reflection layer 30, here is not intended to be limiting.

Therefore, the light emitting module 7 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 7 of the disclosure. Comparing to the illumination product in the related art, the light emitting module 7 of the disclosure may have higher illuminance.

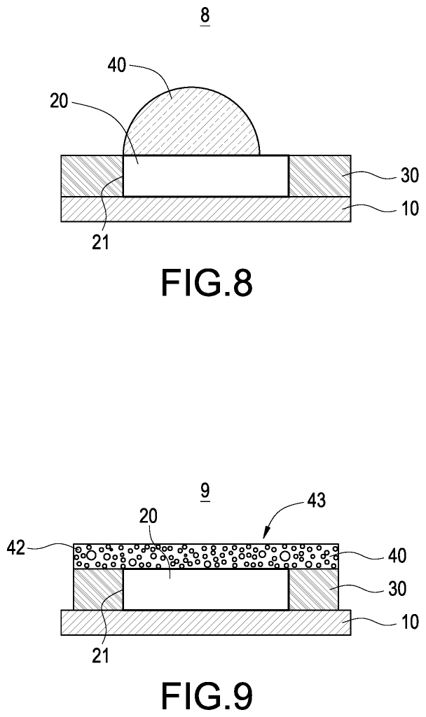

FIG. 8 is a structural perspective view of the eighth embodiment of the light emitting module 8 in the disclosure.

The light emitting module 8 in the eighth embodiment of the disclosure is similar to the light emitting module 7 in the seventh embodiment, the difference is that the fluorescent layer 40 only covers part of the light emitting element 20 and does not cover the whole light emitting element 20, here is not intended to be limiting.

Therefore, the light emitting module 8 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 8 of the disclosure. Comparing to the illumination product in the related art, the light emitting module 8 of the disclosure may have higher illuminance.

FIG. 9 is a structural perspective view of the ninth embodiment of the light emitting module 9 in the disclosure.

The light emitting module 9 in the ninth embodiment of the disclosure is similar to the light emitting module 3 in the third embodiment, the difference is that the fluorescent layer 40 includes an irregular structure in a non-uniform distribution manner.

In some embodiments, the irregular structure includes at least two fluorescent particles 42 with different sizes. As a result, more light may be scattered in the fluorescent layer 40 to reduce total internal reflection (TIR) phenomenon on the light emitting surface 43 and increase the light intensity on the light emitting surface 43.

In some other embodiments, the irregular structure may be only disposed on the light emitting surface 43 without occupying the whole fluorescent layer 40.

Therefore, the light emitting module 9 of the disclosure uses the reflection layer 30 capable of surrounding the side wall 21 of the light emitting element 20. As a result, part of the light outputted from the light emitting element 20 may not escape from the side wall 21 of the light emitting element 20 and may not cause energy waste. Further, the reflection layer 30 restricts the light emitting angle of the light emitting element 20, and makes more light enter the fluorescent layer 40 to increase the illuminance of the light emitting module 9 of the disclosure. Comparing to the illumination product in the related art, the light emitting module 9 of the disclosure may have higher illuminance.

Further, the fluorescent layer 40 with at least two fluorescent particles 42 being mixed may be used to further reduce TIR phenomenon on the light emitting surface 43, and enhance the light intensity on the light emitting surface 43 with respect to the reflection layer 30 surrounding the light emitting element 20.

In summary, the light emitting module of the disclosure uses the reflection layer capable of surrounding the side wall of the light emitting element. As a result, part of the light outputted from the light emitting element may not escape from the side wall of the light emitting element and may not cause energy waste. Further, the reflection layer restricts the light emitting angle of the light emitting element, and makes more light enter the fluorescent layer to increase the illuminance of the light emitting module of the disclosure. Comparing to the illumination product in the related art, the light emitting module of the disclosure may have higher illuminance.

It is worth mentioning that the reflection layer may include a colloid composed of high-molecular material or metal oxide (such as, TiO₂, etc.) in white color with high reflectivity, here is not intended to be limiting.

In some embodiments, depending on the requirement of different illumination products or package sizes, the side walls of the reflection layer or the fluorescent layer may be adjusted to be structured in different types, such as the first step surface, the second step surface, or the third step surface, and the surface of the fluorescent layer may be selectively formed in a curved surface or a flat surface.

In some embodiments, the fluorescent layer may have at least two fluorescent particles being mixed to further reduce TIR phenomenon on the light emitting surface, and enhance the light intensity on the light emitting surface.

Therefore, the light emitting module of the disclosure may overcome the disadvantages of over broad light emitting angle and low illuminance, and comparing with the related art, the present disclosure may increase the illuminance by at least 10%.

While this disclosure has been described by means of specific embodiments, numerous modifications and variations may be made thereto by those skilled in the art without departing from the scope and spirit of this disclosure set forth in the claims.

What is claimed is:

1. A light emitting module, comprising:
a carrier;
a light emitting element, disposed on the carrier;
a reflection layer, disposed on the carrier, and surrounding the light emitting element; and
a fluorescent layer, covering at least part of the light emitting element.

2. The light emitting module according claim 1, wherein the light emitting element comprises a light emitting diode.

3. The light emitting module according claim 1, wherein the fluorescent layer is structured as a curved surface or a flat surface on the light emitting element.

4. The light emitting module according claim 1, wherein the fluorescent layer further covers a least part of the reflection layer.

5. The light emitting module according claim 1, wherein a side wall of the reflection layer is structured as a first step surface.

6. The light emitting module according claim 1, wherein a second step surface is disposed between the carrier and the reflection layer.

7. The light emitting module according claim 1, wherein a third step surface is disposed between the reflection layer and the fluorescent layer.

8. The light emitting module according claim 1, wherein the fluorescent layer comprises an irregular structure in a non-uniform distribution manner.

9. The light emitting module according claim 8, wherein the irregular structure comprises at least 1

10. The light emitting module according claim 8, wherein the irregular structure is only disposed on a light emitting surface of the fluorescent layer.
